(19) United States
(12) Patent Application Publication
(10) Pub. No.: US 2007/0160935 A1
(43) Pub. Date: Jul. 12, 2007

(54) Lithographic printing plate material for CTP

(76) Inventor: Keiichi Okajima, Osaka (JP)

Correspondence Address: WENDEROTH, LIND & PONACK, L.L.P., 2033 K STREET N. W., SUITE 800, WASHINGTON, DC, 20006-1021, US

(21) Appl. No.: 11/652,540

(22) Filed: Jan. 12, 2007

(30) Foreign Application Priority Data
Jan. 12, 2006 (JP) 2006-4776

(51) Int. Cl. G03F 7/00

(52) U.S. Cl. 430/302

(57) ABSTRACT

The present invention relates to a lithographic printing plate material for CTP, which comprises a substrate, a photosensitive layer formed on the substrate, and a dye-containing layer formed on the photosensitive layer, wherein the photosensitive layer is formed by a photosensitive composition comprising a halomethyl group-containing compound and an organoboron anion-containing compound, and wherein the dye-containing layer is formed by a composition for dye-containing layer, which comprises a near-infrared-absorbing dye. Accordingly, the present invention can provide a lithographic printing plate material for CTP comprising a substrate, a photosensitive layer and a dye-containing layer formed on the photosensitive layer, a producing method therefor, as well as a method for producing a printing plate from the printing plate material and a printing prate produced thereby.

### TECHNICAL FIELD

The present invention relates to a lithographic printing plate material for CTP (Computer to Plate), which comprises an aluminum substrate, a photosensitive layer formed on the aluminum substrate and a protective layer formed on the photosensitive layer, and a producing method therefor as well as a method for producing a printing plate from the printing plate material, and a printing plate produced thereby.

### BACKGROUND OF THE INVENTION

Lithographic printing plate has a printing system wherein imaged area of a resin composition layer having thickness of few microns, which is lipophilic, receives ink and non-imaged area of an exposed substrate, which has been subjected to hydrophilization, receives water in order to print an article. As photosensitive material for such photosensitive lithographic printing plate, photopolymerizable photosensitive resin compositions are widely utilized in the art of printing. Because the increased degree of photocrosslinking provides tough films, appropriate selection of initiator comparatively facilitates high sensitization, and the like. Recently, technologies, especially in the field of computers and lasers, are significantly developing, and therefore, a method for directly forming an image, after electronic data processing, on a layer of photopolymerizable photosensitive resin composition with exposing to scanning laser light, which formed image is developed to provide a printing plate, is under consideration. This method is referred to as Computer to Plate (CTP) method.

Laser light source includes many conventional sources such as semiconductor lasers at 355 nm (ultraviolet), semiconductor lasers at 405 nm (violet), argon lasers at 488 nm (blue), FD-YAG lasers at 532 nm (green), helium-neon lasers at 633 nm (red), semiconductor lasers at 670 nm (red), semiconductor lasers at 780 nm (near-infrared), semiconductor lasers at 830 nm (near-infrared), YAG lasers at 1064 nm (infrared), etc. Recently, semiconductor lasers having wavelength within near-infrared or infrared area, which can provide high energy, especially semiconductor lasers at 830 nm (near-infrared) are remarkable.

For example, a photopolymerizable photosensitive composition which can be employed in direct formation of an image with one of the above-described semiconductor lasers at 830 nm after electronic data processing, and a lithographic printing plate material for CTP utilizing the composition are suggested, for example, in JP-B-3321288 corresponding to U.S. Pat. No. 5,496,903, etc. JP-B-3321288 discloses a method comprising use of a mixture of a near-infrared-absorbing dye, a halomethyl group-containing compound and an organoboron anion-containing compound as a photopolymerization initiator for the photosensitive composition.

JP-A-2005-275032 also suggests a photosensitive lithographic printing plate obtainable by applying on a substrate a photosensitive layer containing an alkali-soluble polymer having an ethylenically unsaturated double bond in a side chain and a carboxyl group-containing monomer residue as a copolymerization component; a trihaloalkyl-substituted compound as a photopolymerization initiator; an organoborate or a combination thereof; and a sensitizing dye having absorption at 750 to 900 nm and capable of sensitizing the photopolymerization initiator, and by further applying an overcoat layer on the photosensitive layer, wherein a dye having absorption from 750 to 900 nm is contained in the overcoat layer, in order to prevent banding due to multichannel infrared laser scanning exposure.

### SUMMARY OF THE INVENTION

According to JP-B-3321288, there is a problem that a sensitizing solution using and containing a mixture of a near-infrared-absorbing dye, a halomethyl group-containing compound and an organoboron anion-containing compound as a photopolymerization initiator has short shelf life, herein shelf life means storage life, i.e. maximum period which can keep the conditions of the sensitizing solution still remain at the same as it was prepared and stored, and the sensitizing solution can be used appropriately. The reasons for the short shelf life are considered that when both of the near-infrared-absorbing dye and the organoboron anion-containing compound are present in the solution, reactions such as salt exchange take place to produce insoluble materials (i.e. blobbing) and the effective ingredients as initiator are deactivated at the same time.

According to JP-A-2005-275032, there is also the same problem that the sensitizing solution to form the photosensitive layer, which comprises the trihaloalkyl-substituted compound and the organoborate and the sensitizing dye having absorption at 750 to 900 nm, has short shelf life.

The present invention is to solve the above-described problems associated with the conventional lithographic printing plate materials for CTP. The objects of the present invention consists in a provision of a lithographic printing plate material for CTP having excellent image remaining property, printing durability and stability in a bright room, which can be subjected to development with an aqueous alkaline-developer, and achievement of longer shelf life of sensitizing solution using and containing a near-infrared-absorbing dye, a halomethyl group-containing compound and an organoboron anion-containing compound, as a photopolymerization initiator. Herein, stability in a bright room means storage stability under a bright safe light such as ultraviolet screened all-round light or yellow light, which stability improves the handling ability upon exposing and drawing on a photosensitive lithographic printing plate.

The present inventor studied intensively to solve these problems and found that a lithographic printing plate material for CTP, which comprises an aluminum substrate, a photosensitive layer and a dye-containing layer, wherein the photosensitive layer is formed by a photosensitive composition comprising an ethylenically unsaturated compound, an alkali-soluble resin, a halomethyl group-containing compound and an organoboron anion-containing compound, and wherein the dye-containing layer is formed by a composition for dye-containing layer, which comprises a near-infrared-absorbing dye and a water-soluble or alkali-soluble resin, can be provided and significantly improve shelf life of the sensitizing solution containing them, and provide excellent image remaining property, printing durability and stability in a bright room, and can be subjected to development with an aqueous alkaline-developer.

Accordingly, the present invention relate to a lithographic printing plate material for CTP, which comprises
a substrate,
a photosensitive layer formed on the substrate, and
a dye-containing layer formed on the photosensitive layer,
wherein the-photosensitive layer is formed by a photosensitive composition comprising a halomethyl group-containing compound and an organoboron anion-containing compound, and wherein
the dye-containing layer is formed by a composition for dye-containing layer, which comprises a near-infrared-absorbing dye.

Furthermore, in order to preferably carry out the present invention, it is more preferable that

the photosensitive composition is free of a near-infrared-absorbing dye;

the substrate is an aluminum substrate, and the composition for dye-containing layer further comprises a water-soluble or alkali-soluble resin (A);

the photosensitive composition further comprises an ethylenically unsaturated compound and an alkali-soluble resin (B);

the photosensitive composition comprises 0.1 to 20 parts by weight of the halomethyl group-containing compound and 0.1 to 20 parts by weight of the organoboron anion-containing compound, relative to 100 parts by weight of the ethylenically unsaturated compound and the alkali-soluble resin (B), and the weight ratio of the ethylenically unsaturated compound: the alkali-soluble resin (B) is 40:60 to 90:10;

content of the near-infrared-absorbing dye is 0.1 to 30 parts by weight relative to 100 parts by weight of solid content of the composition for dye-containing layer;

the photosensitive composition and/or the composition for dye-containing layer further comprise(s) a nitroxyl compound;

the photosensitive composition comprises 0.001 to 1 part by weight of the nitroxyl compound relative to 100 parts by weight of total amount of the ethylenically unsaturated compound and the alkali-soluble resin (B) with the proviso that the nitroxyl compound is comprised only in the photosensitive composition;
the composition for dye-containing layer comprises 0.001 to 1 part by weight of the nitroxyl compound relative to 100 parts by weight of solid content of the composition for dye-containing layer with the proviso that the nitroxyl compound is comprised only in the composition for dye-containing layer; or
the photosensitive composition comprises 0.001 to 1 part by weight of the nitroxyl compound relative to 100 parts by weight of total amount of the ethylenically unsaturated compound and the alkali-soluble resin (B), and the composition for dye-containing layer comprises 0.001 to 1 part by weight of the nitroxyl compound relative to 100 parts by weight of solid content of the composition for dye-containing layer, with the proviso that the nitroxyl compound is comprised in both of the photosensitive composition and the composition for dye-containing layer;

the composition for dye-containing layer further comprises an organic pigment;

the photosensitive layer is applied in an amount of 0.5 to 2.0 g/m² (as a basis of the solid content) and the dye-containing layer is applied in an amount of 0.5 to 2.5 g/m² (as a basis of the solid content);

the photosensitive composition or the composition for dye-containing layer further comprises 0.05 to 0.5 part by weight of a matting agent relative to 100 parts by weight of solid content of the photosensitive composition or the composition for dye-containing layer; and/or

the substrate is an aluminum substrate, and the present lithographic printing plate material further comprises the third layer on the dye-containing layer, which comprises a water-soluble or alkali-soluble resin (A).

It is more preferable that the dye-containing layer is applied in an amount of 0.5 to 2.5 g/m² as a coating thickness (as a basis of the solid content);
the dye-containing layer comprises 0.1 to 30 parts by weight of the near-infrared-absorbing dye relative to 100 parts by weight of solid content of the dye-containing layer;
the dye-containing layer comprises 0.001 to 1 part by weight of the nitroxyl compound relative to 100 parts by weight of solid content of the dye-containing layer; and/or the composition for the dye-containing layer comprises an organic solvent to the total content to be 100%, as a solvent component, which can solubilize the near-infrared-absorbing dye, the water-soluble or alkali-soluble resin and the nitroxyl compound.

Other embodiment of the present invention is a method for producing a lithographic printing plate material for CTP, which comprises
(a) forming a photosensitive layer on a substrate, and
(b) forming a dye-containing layer on the photosensitive layer, wherein
a photosensitive composition comprising an ethylenically unsaturated compound, an alkali-soluble resin, a halomethyl group-containing compound and an organoboron anion-containing compound is applied and dried to form the photosensitive layer, and wherein
a composition for dye-containing layer, which comprises a near-infrared-absorbing dye and a water-soluble or alkali-soluble resin, is applied and dried to form the dye-containing layer.

Furthermore, in order to preferably carry out the present invention, it is preferable that the photosensitive layer and/or the dye-containing layer further comprises a nitroxyl compound.

Still further embodiments of the present invention are a method for producing a lithographic printing plate for CTP, which comprises, on the lithographic printing plate material for CTP,
(i) exposing and drawing with a semiconductor laser having wavelength of 830 nm as a light source,
(ii) optionally rinsing the dye-containing layer with water to remove the layer,
(iii) developing the photosensitive layer, together with the dye-containing layer, with an alkaline-aqueous developer with the proviso that the dye-containing layer has not been rinsed with water not to remove the layer in the above step (ii),
(iv) treating with a desensitizing agent, and
(v) optionally heating; as well as a lithographic printing plate for CTP produced according to the above-described method.

The present invention can provide a lithographic printing plate material for CTP, which preferably comprises an aluminum substrate, a photosensitive layer and a dye-containing layer, wherein the photosensitive layer is formed by a photosensitive composition comprising an ethylenically unsaturated compound, an alkali-soluble resin, a halomethyl group-containing compound and an organoboron anion-containing compound, and wherein the dye-containing layer is formed by a composition for dye-containing layer which comprises a near-infrared-absorbing dye, in order to significantly improve shelf life of a sensitizing solution containing them, and to provide excellent image remaining property, printing durability and stability in a bright room, which can be subjected to development with an aqueous alkaline-developer.

### DETAILED DESCRIPTION OF THE PREFERRED EMBODIMENTS

The present lithographic printing plate material for CTP is further described in detail hereinafter. The present lithographic printing plate material for CTP comprises a substrate, a photosensitive layer formed on the substrate and a dye-containing layer formed on the photosensitive layer. The present lithographic printing plate material for CTP may further comprise the third layer on the dye-containing layer.

Substrate

The preferable substrate includes an aluminum substrate. It is more preferable that the aluminum substrate has been mechanically surface roughened, chemically or electrically etched, and/or subjected to anodic oxidation. Methods for mechanically surface roughening include known methods such as ball polishing, brush polishing, blast polishing, and buff polishing. Chemically etching methods include etching with acid or alkali. Electrically etching methods include applying alternating or direct current in an electrolysis solution containing hydrochloric acid or nitric acid. Methods for anodic oxidation include applying current to aluminum anode and aqueous solution containing 1 or 2 or more of inorganic acids such as phosphoric acid, sulfuric acid, chromic acid and/or organic acids such as oxalic acid.

It is still more preferably that the substrate after anodic oxidation is further subjected to hydrophilization. Hydrophilization includes widely known methods such as a method comprising silicate treatment with an alkali metal silicate, a method comprising treatment with a polyphosphonic acid or a derivative thereof, a method comprising treatment with potassium hexafluoro zirconate, etc. Further preferable treatment includes a method comprising silicate treatment with an alkali-metal silicate such as sodium silicate, potassium silicate, lithium silicate, etc.

Preferable thickness of the substrate is 0.1 to 1.6 mm, more preferably 0.25 to 0.55 mm. When the thickness of the substrate is less than 0.1 mm, the printing plate material and printing plate sometimes break on handling them, particularly carrying them in hand. When the thickness is more than 1.6 mm, it increases cost of the printing plate material, renders the printing plate material weighted and results in frequent jamming in an exposure apparatus.

Photosensitive Layer

The photosensitive composition which is to be formed to the photosensitive layer comprised in the present invention is further described in detail hereinafter. The photosensitive composition comprises a halomethyl group-containing compound and an organoboron anion-containing compound. The photosensitive composition further comprises an ethylenically unsaturated compound and an alkali-soluble resin.

Halomethyl Group-Containing Compound

The halomethyl group-containing compounds which can be employed in the photosensitive composition include S-triazine compounds having at least one of methyl groups wherein at least one of the hydrogen atoms therein is substituted with chlorine atom(s) or bromine atom(s), such as S-triazine compound represented by Formula: 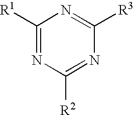
wherein R¹, R² and R³ are each independently a trichloromethyl group, an alkyl group having 1 to 10 carbon atoms, which may preferably have 1 to 4 substituents, an aryl group having 6 to 15, preferably 6 to 10 carbon atoms, an aralkyl group having 7 to 25, preferably 7 to 14 carbon atoms, an alkoxy group having 1 to 10, preferably 1 to 4 carbon atoms, an alkenyl group having 2 to 15, preferably 2 to 10 carbon atoms, a piperidino group, a piperonyl group, an amino group, a dialkylamino group having 2 to 20, preferably 2 to 8 carbon atoms, a thiol group or an alkylthio group having 1 to 10, preferably 1 to 4 carbon atoms, with the proviso that at least one of R¹ to R³ is a trichloromethyl group;
preferably such S-triazine compounds wherein at least one of the trichloromethyl groups is attached to the carbon atom in the S-triazine structure, as well as, compounds having a tribromomethylsulfonyl group, such as tribromomethylphenylsulfone, 2-tribromomethylsulfonyl-pyridine and 2-tribromomethylsulfonylbenzthiazole, etc.

Particularly preferable examples of the S-triazine compounds, which can be used in the present invention, include 2,4,6-tris(trichloromethyl)-S-triazine, 2-methyl-4,6-bis(trichloromethyl)-S-triazine, 2-methoxy-4,6-bis(trichloromethyl)-S-triazine, 2-phenyl-4,6-bis(trichloromethyl)-S-triazine, 2-(p-methoxyphenyl)-4,6-bis(trichloromethyl)-S-triazine, 2-(4-methylthiophenyl)-4,6-bis(trichloromethyl)-S-triazine, 2-(p-chlorophenyl)-4,6-bis(trichloromethyl)-S-triazine, 2-(4-methoxynaphthyl)-4,6-bis(trichloromethyl)-S-triazine, 2-piperonyl-4,6-bis(trichloromethyl)-S-triazine, 2-piperidino-4,6-bis(trichloromethyl)-S-triazine, 2-styryl-4,6-bis(trichloromethyl)-S-triazine, 2-(p-methoxystyryl)-4,6-bis(trichloromethyl)-S-triazine, 2-(3,4-dimethoxystyryl)-4,6-bis(trichloromethyl)-S-triazine, 2-(p-dimethylamino-styryl)-4,6-bis(trichloromethyl)-S-triazine.

Organoboron Anion-Containing Compound

The organoboron anion-containing compound which can be employed in the photosensitive composition can be represented by Formula (a): 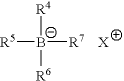
wherein
R⁴, R⁵, R⁶ and R⁷ are each independently an alkyl group having 1 to 10 carbon atoms, an aryl group having 6 to 15 carbon atoms, an alkaryl group having 2 to 10 carbon atoms, an allyl group, an aralkyl group having 1 to 10 carbon atoms, an alkenyl group having 1 to 10 carbon atoms or an alkynyl group having 1 to 10 carbon atoms, each of which may have a substituent, and
X⁺ is a counter cation, an alkali metal cation (e.g. sodium cation and lithium cation) or a phosphonium cation. It is desirable that the organoboron anion-containing compound is selected from a compound represented by Formula (b): 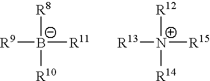
   wherein
R⁸, R⁹, R¹⁰ and R¹¹ are each independently an alkyl group having 1 to 10 carbon atoms, an aryl group having 6 to 15 carbon atoms, an alkaryl group having 2 to 10 carbon atoms, an allyl group, an aralkyl group having 1 to 10 carbon atoms, an alkenyl group having 1 to 10 carbon atoms or an alkynyl group having 1 to 10 carbon atoms, each of which may have a substituent, with the proviso that at least one of R⁸, R⁹, R¹⁰ and R¹¹ is preferably an alkyl group, and R¹², R¹³, R¹⁴ and R¹⁵ are each independently an alkyl group having 1 to 10 carbon atoms, an aryl group having 6 to 15 carbon atoms, an alkaryl group having 2 to 10 carbon atoms, an allyl group, an aralkyl group having 1 to 10 carbon atoms, an alkenyl group having 1 to 10 carbon atoms, an alkynyl group having 1 to 10 carbon atoms, a silyl group, an alicyclic group or a heterocyclic group, each of which may have a substituent and/or a cyclic structure.

The organoboron anion-containing compound represented by the Formula (a) includes, for example, sodium tetraphenylborate, lithium triphenyl-n-butylborate, tetraphenylphosphonium tetrakis(4-methylphenyl)borate, tetraphenylphosphonium tetraphenylborate, benzyltriphenylphosphonium tetraphenylborate, 4-methylphenyltriphenylphosphonium tetrakis(4-methylphenyl)-borate, and the like.

The organoboron anion-containing compound represented by the Formula (b) includes, for example, tetramethylammonium tetraphenylborate, tetraethylammonium tetraphenylborate, tetramethylammonium tetraanisylborate, 1,5-diazabicyclo[4.3.0]nonene-5-tetraphenylborate, 1,8-diazabicyclo[5.4.0]undecene-7-tetraphenylborate, 2-ethyl-4-methylimidazolium tetraphenylborate, tetramethylammonium triphenyl-n-butylborate, tetramethylammonium triphenyl n-octylborate, tetraethylammonium triphenyl-n-butylborate, tetramethylammonium trianisyl-n-butylborate, tetraethylammonium diphenyl-di-n-butylborate, and the like.

Ethylenically Unsaturated Compound

The ethylenically unsaturated compounds which may be employed in the photosensitive composition include, but are not particularly limited to, compounds having an ethylenically unsaturated double bond, which are subjected to radical addition polymerization in the presence of a photopolymerization initiator, in order to be cured.

For example, the ethylenically unsaturated compounds include acrylic acid, methacrylic acid, methyl(meth)acrylate, ethyl(meth)acrylate, n-propyl(meth)acrylate, iso-propyl(meth)acrylate, n-butyl(meth)acrylate, iso-butyl(meth)acrylate, sec-butyl(meth)acrylate, t-butyl(meth)acrylate, 2-ethylhexyl(meth)acrylate, n-nonyl(meth)acrylate, n-decyl(meth)acrylate, lauryl(meth)acrylate, n-tridecyl(meth)acrylate, stearyl(meth)acrylate, ethyleneglycol mono(meth)acrylate, propyleneglycol mono(meth)acrylate, diethyleneglycol mono(meth)acrylate, dipropyleneglycol mono(meth)acrylate, polyethyleneglycol mono(meth)acrylate having molecular weight of 200 to 1,000, polypropyleneglycol mono(meth)acrylate having molecular weight of 200 to 1,000, polyethyleneglycol-monomethyl ether mono(meth)acrylate having molecular weight of 200 to 1,000, polypropyleneglycol-monomethyl ether mono(meth)acrylate having molecular weight of 200 to 1,000, polyethyleneglycol-monoethyl ether mono(meth)acrylate having molecular weight of 200 to 1,000, polypropyleneglycol-monoethyl ether mono(meth)acrylate having molecular weight of 200 to 1,000, n-butoxyethyl(meth)acrylate, phenoxy ethyl(meth)acrylate, 2-phenoxypropyl(meth)acrylate, cyclohexyl(meth)acrylate, tetrahydrofurfuryl(meth)acrylate, glycidyl(meth)acrylate, allyl(meth)acrylate, benzyl(meth)acrylate, tribromophenyl(meth)acrylate, 2,3-dichloropropyl(meth)acrylate, 3-chloro-2-hydroxypropyl(meth)acrylate, N,N-diethylaminoethyl(meth)acrylate, N,N-dimethylaminoethyl(meth)acrylate, N-t-butylaminoethyl(meth)acrylate, ethyleneglycol di(meth)acrylate, propyleneglycol di(meth)acrylate, 1,3-propanediol di(meth)acrylate, 1,4-butanediol di(meth)acrylate, neopentylglycol di(meth)acrylate, 1,6-hexanediol di(meth)acrylate, polyethyleneglycol di(meth)acrylate, polypropyleneglycol di(meth)acrylate, glycerol di(meth)acrylate, glycerol tri(meth)acrylate, trimethylolpropane tri(meth)acrylate and trimethylolethane tri(meth)acrylate; acrylamide, ethylenebisacrylamide, ethylenebismethacrylamide, hexamethylenebisacrylamide, hexamethylenebismethacrylamide, and the like.

Preferably, the ethylenically unsaturated compounds also comprise
(I) polyurethane(meth)acrylate obtainable by reacting the following components:
(i) polyester polyol which can be obtained by, for example, reacting a diol component, such as ethyleneglycol, diethyleneglycol and 1,3-butyleneglycol, with an acid component such as dibasic acid (e.g., phthalic acid, tetrahydrophthalic acid and hexahydrophthalic acid) and anhydride thereof;
(ii) polyisocyanate (e.g., tolylenediisocyanate, 4,4′-diphenylmethanediisocyanate, isophoronediisocyanate, hexamethylenediisocyanate and the like); and
(iii) hydroxy group-containing (meth)acrylate (e.g., 2-hydroxyethyl(meth)acrylate, 2-hydroxypropyl(meth)acrylate, glycerol di(meth)acrylate, pentaerythritol tri(meth)acrylate, dipentaerythritol penta(meth)acrylate and the like);
(II) polyurethane(meth)acrylate obtainable by reacting the following components:
(i) compound having no less than three isocyanate groups therein, which is disclosed in JP-A-10-90886 (e.g., isocyanurates, burettes and adducts of diisocyanates); and
(ii) hydroxyl group-containing (meth)acrylate (e.g., 2-hydroxypropyl(meth)acrylate, 2-hydroxypropyl(meth)acrylate, glycerol di(meth)acrylate, pentaerythritol tri(meth)acrylate, dipentaerythritol penta(meth)acrylate and the like);
(III) bisphenol type epoxy acrylate obtainable by reacting bisphenol type epoxy resin (e.g., Epikote 828, Epikote 1001, Epikote 1004 and Epikote 807 by Shell, and the like) with (meth)acrylic acid;
(IV) novolac type epoxy acrylate obtainable by reacting novolac type epoxy resin (e.g., Epikote 152 and Epikote 154 by Shell) with (meth)acrylic acid; and the like.

Among the above-described compounds, the ethylenically unsaturated compound which may be employed in the photosensitive composition are desirably such compounds having no less than 2, preferably 3 to 15, more preferably 4 to 15 of (meth)acryl groups and/or having molecular weight of 300 to 3,000, preferably 500 to 3,000. When the ethylenically unsaturated compound contains less than two of (meth)acryl groups, it provides poor printing durability. When the ethylenically unsaturated compound has molecular weight of less than 300, it provides higher crosslinking density and poor chipping resistance, and therefore it results in poor printing durability. When the compound has molecular weight of more than 3,000, it provides lower crosslinking density resulting poor printing durability.

Alkali-Soluble Resin (B)

The alkali-soluble resin (B), which can be employed in the photosensitive composition, includes a resin having a carboxylic group as side chain, a resin having a carboxyl group and ethylenically unsaturated group as side chain, and mixture thereof. The ethylenically unsaturated group can be introduced by reacting the carboxylic group of the side chain of the alkali-soluble resin with an epoxy group-containing ethylenically unsaturated compound. The epoxy group-containing ethylenically unsaturated compound includes compounds such as Compound (III) having an epoxy group, and a (meth)acryloyl group or a vinyl group optionally having a methyl substituent, which is disclosed in JP-B-2758737 corresponding to U.S. Pat. No. 5,378,579; alicyclic epoxy group-containing unsaturated compound having a radical polymerizable unsaturated group and an alicyclic epoxy group in a molecule, which is disclosed in JP-B-2763775; and the like. Preferable epoxy group-containing unsaturated compounds include glycidyl(meth)acrylate, (meth)aclylates having an alicyclic epoxy group, etc.

For example, the alkali-soluble resin (B) includes resins obtainable by self-polymerization of monomer compound such as unsaturated carboxyl acids and derivatives thereof (e.g., (meth)acrylic acid, 2-succinoyloxyethyl methacrylate, 2-maleinoyloxyethyl methacrylate, 2-phthaloyloxyethyl methacrylate, 2-hexahydrophthaloyloxyethyl methacrylate, maleic acid, fumaric acid, itaconic acid and crotonic acid), and resins obtainable by copolymerization of the above cited unsaturated carboxyl acid or its derivative and at least one of vinyl monomers without carboxyl group.

The vinyl monomers without carboxyl group include
(I) hydroxyl group-containing monomers, such as 2-hydroxyethyl acrylate, hydroxypropylacrylate, 2-hydroxyethyl methacrylate, hydroxypropyl methacrylate, hydroxybutyl acrylate, hydroxybutyl methacrylate, allyl alcohol, methallyl alcohol, N-(4-hydroxyphenyl)acrylamide, N-(4-hydroxyphenyl)methacrylamide, o-, m- or p-hydroxystyrene, o-, m- or p-hydroxyphenyl acrylate and o-, m- or p-hydroxyphenyl methacrylate;
(II) alkyl(meth)acrylates, such as methyl(meth)acrylate, ethyl(meth)acrylate, n-butyl(meth)acrylate, propyl(meth)acrylate, acyl(meth)acrylate, cyclohexyl(meth)acrylate, octyl acrylate and 2-chloroethyl acrylate;
(III) polymerizable amides, such as (meth)acrylamides (e.g., acrylamide, methacrylamide, N-methylolacrylamide, N-methylolmethacrylamide, N-ethylacrylamide, N-hexylacrylamide, N-cyclohexylacrylamide, N-hydroxyethylacrylamide, N-phenylacrylamide, N-nitrophenylamide and N-ethyl-N-phenylacrylamide);
(IV) nitrogen-containing alkyl(meth)acrylates, such as dimethylaminoethyl acrylate and dimethylaminoethyl methacrylate;
(V) vinyl ethers, such as ethylvinyl ether, 2-chloroethyl vinyl ether, hydroxyethyl vinyl ether, propyl vinyl ether, butyl vinyl ether, octyl vinyl ether, and phenyl vinyl ether;
(VI) vinyl esters, such as vinyl acetate, vinyl chloroacetate, vinyl butylate and vinyl benzoate;
(VII) styrenes, such as styrene, α-methylstyrene, methylstyrene and chloromethylstyrene;
(VIII) vinyl ketones, such as methyl vinyl ketone, ethyl vinyl ketone, propyl vinyl ketone and phenyl vinyl ketone;
(IX) olefins, such as ethylene, propylene, isobutylene, butadiene and isoprene;
(X) glycidyl(meth)acrylate;
(XI) polymerizable nitriles, such as acrylonitrile and methacrylonitrile;
(XII) N-vinylpyrrolidone, N-vinylcarbazole and 4-vinylpyridine;
(XIII) zwitter-ion type monomers, such as N,N-dimethyl-N-methacryloxyethyl-N-(3-sulfopropyl)-ammonium-betaine, N,N-dimethyl-N-methacrylamidepropyl-N-(3-sulfopropyl)-ammonium-betaine and 1-(3-sulfopropyl)-2-vinylpyridinium-betaine;
and the like.

The alkali-soluble resins also include resins obtainable by copolymerization of maleic anhydride and a monomer such as styrene and α-methylstyrene, and subsequent half-esterification with monoalcohol such as methanol, ethanol, propanol, butanol and hydroxyethyl(meth)acrylate, or hydrolysis with water.

Alternatively, the alkali-soluble resins include resins obtainable by addition of an unsaturated carboxyl acid or derivative thereof, such as (meth)acrylic acid, 2-succinoyloxyethyl methacrylate, 2-maleinoyloxyethyl methacrylate, 2-phthaloyloxyethyl methacrylate, 2-hexahydrophthaloyloxyethyl methacrylate, maleic acid, fumaric acid, itaconic acid and crotonic acid, or a saturated carboxyl acid such as acetic acid, propionic acid and stearic acid, to a resin such as novolac epoxy acrylate resin and bisphenol epoxy resin, and subsequent modification with an acid anhydride such as maleic anhydride, itaconic anhydride, tetrahydrophthalic anhydride and phthalic anhydride.

Among others, acrylic resins are preferably employed as alkali-soluble resin, since these acrylic resins are readily prepared and have compatibility with the ethylenically unsaturated compound as described above. For example, the preferable acrylic resins include methyl methacrylate/methacrylic acid copolymer, methyl methacrylate/methyl acrylate/methacrylic acid copolymer, benzyl methacrylate/methyl methacrylate/2-ethylhexyl methacrylate/methacrylic acid copolymer, methyl methacrylate/n-butyl methacrylate/2-ethylhexyl acrylate/methacrylic acid copolymer, styrene/acrylic acid copolymer, styrene/methacrylic acid copolymer, styrene/methyl methacrylate/methyl acrylate/methacrylic acid copolymer, styrene/methyl methacrylate/2-hydroxyethyl methacrylate/methacrylic acid copolymer, methyl methacrylate/n-butyl acrylate/2-ethylhexyl acrylate/methacrylic acid copolymer, methyl methacrylate/n-butyl acrylate/2-ethylhexyl acrylate/styrene/methacrylic acid copolymer, and the like.

According to the present invention, the alkali-soluble resin having ethylenically unsaturated groups as side chain may be used in combination with an alkali-insoluble resin having ethylenically unsaturated groups as side chain, such as the above-described alkali-soluble resin having carboxyl groups, all of which carboxyl groups had been reacted with epoxy group-containing ethylenically unsaturated compound(s), such as glycidyl(meth)acrylate and 3,4-epoxycyclohexylmethyl(meth)acrylate, wherein the reaction proceeded on the epoxy moiety; and an alkali-insoluble resin having hydroxyl groups which had been reacted with an isocyanate group-containing ethylenically unsaturated compound, such as methacryloyl isocyanate, 2-isocyanatoethyl acrylate, 2-isocyanoethyl methacrylate and 1,1-bis(acryloyloxymethyl)ethyl isocyanate, wherein the reaction proceeded on the isocyanate moiety; and the like. Alternatively, another alkali-insoluble resins having ethylenically unsaturated group(s) as side chain can be prepared in accordance with a method known to those skilled in the art and may be employed in the present invention.

Consequently, it is appreciated that the alkali-soluble resin (B) combined with the alkali-insoluble resin has alkali-solubility. Hereinafter, the alkali-soluble resin combined with the alkali-insoluble resin may be abbreviated to an “alkali-soluble resin”, whose properties are considered as those of the mixture.

The alkali-soluble resin which may be employed in the present invention desirably has acid value of 30 to 150 KOH mg/g, preferably 50 to 130 KOH mg/g, and weight average molecular weight of 5,000 to 200,000, preferably 10,000 to 200,000. When the acid value of the alkali-soluble resin is less than 30 KOH mg/g, it provides insufficient alkaline development. When the acid value is more than 150 KOH mg/g, it provides sufficient alkaline development and a thinner layer resulting poor image remaining property.

When the weight average molecular weight of the alkali-soluble resin is less than 5,000, it provides poor printing durability and poor solid-retaining ability, even if the products such as printing plate materials demand solid-retaining ability. When the weight average molecular weight is more than 200,000, it provides poor alkaline development ability.

In the photosensitive composition which may be employed in the present invention, content of the halomethyl group-containing compound is 0.1 to 20 parts by weight, preferably 1 to 10 parts by weight relative to 100 parts by weight of total amount of the ethylenically unsaturated compound and the alkali-soluble resin. When the content of the halomethyl group-containing compound is less than 0.1 part by weight, it provides insufficient curing. When the content is more than 20 parts by weight, it provides poor solvent resistance of the cured composition, etc.

In the photosensitive composition, content of the organoboron anion-containing compound is 0.1 to 20 parts by weight, preferably 1 to 10 parts by weight relative to 100 parts by weight of total amount of the ethylenically unsaturated compound and the alkali-soluble resin. When the content of the organoboron anion-containing compound is less than 0.1 part by weight, it provides insufficient curing. When the content is more than 20 parts by weight, it provides poor solvent resistance of the cured composition, etc.

The content of the ethylenically unsaturated compound is desirably 30 to 90% by weight, preferably 40 to 80% by weight relative to the total weight of the above-mentioned photosensitive composition. When the content of the ethylenically unsaturated compound is less than 30% by weight, sensitivity is decreased and then printing durability is lowered. When the content is more than 90% by weight, it provides poor solid-retaining ability, even if the products such as printing plate materials demand solid-retaining ability.

The weight ratio of the ethylenically unsaturated compound to the alkali-soluble resin is 40:60 to 90:10, preferably 50:50 to 90:10, more preferably 60:40 to 90:10 (ethylenically unsaturated compound : alkali-soluble resin (w/w)). When the content of the alkali-soluble resin is less than 10% by weight, it provides poor alkaline development ability and poor solid-retaining ability. When the content of the alkali-soluble resin is more than 60% by weight, it provides poor printing durability.

Other Additive

Further additives may be incorporated in the photosensitive composition, which can be subjected to alkaline development, such as solvents (e.g. ketone solvents such as methyl ethyl ketone, acetone, cyclohexanone; ester solvents such as ethyl acetate, butyl acetate, ethyleneglycol diacetate; aromatic solvents such as toluene, xylene; cellosolve solvents such as methylcellosolve, ethylcellosolve, butylcellosolve; alcohol solvents such as methanol, ethanol, propanol; ether solvents such as tetrahydrofuran, dioxane; halogen-containing solvents such as dichloromethane, chloroform; and the like), matting agents, loading agents, heat-polymerization inhibitors, plasticizers, surfactants to improve coating properties, anti-foam agent and inorganic or organic fine particle fillers. Preferable inorganic fillers include silica fine powder (particle size: 0.001 to 2 μm) and colloidal silica dispersed in a solvent (particle size: 0.001 to 1 μm). Preferable organic fillers include microgel which core is gel (particle size: 0.01 to 5 μm). For example, such particularly preferable microgel is disclosed in JP-A-4-274428 corresponding to U.S. Pat. No. 5,393,637, wherein microgel having particle size of 0.01 to 2 μm is prepared by emulsion polymerization comprising use of a polymer emulsifier having Sp value of 9 to 16.

The photosensitive composition, which can be employed in the present invention, can be prepared in accordance with the conventional methods, for example, which include mechanically stirring and mixing the above components such as the ethylenically unsaturated compound, the alkali-soluble resin, the halomethyl group-containing compound and the organoboron anion-containing compound, and the additive, if necessary, under shading with an apparatus known to those skilled in the art, such as high speed stirrers.

The photosensitive layer comprised in the present invention is desirably applied in an amount of 0.5 to 2.0 g/m², preferably 0.5 to 1.5 g/m², more preferably 0.5 to 1.0 g/m² as a basis of the solid content. When the applied amount is less than 0.5 g/m², the surface of the aluminum substrate can not be completely coated due to the great surface roughness of the aluminum substrate. When the applied amount is more than 2.0 g/m², it requires a large amount of heat energy for drying, and there is possibility that the initiator is deactivated during the drying.

Dye-Containing Layer

The dye-containing layer employed in the present invention can be formed by applying a composition for dye-containing layer, which comprises a near-infrared-absorbing dye and an optional water-soluble or alkali-soluble resin (A), on the photosensitive layer formed by the photosensitive composition as described above, and then drying the composition. Generally, photosensitive composition which is photopolymerizable and can be subjected to a radical chain polymerization reaction is effective for the photosensitive layer of the photosensitive lithographic printing plate, especially for its higher sensitization. However, since the chain polymerization is inhibited at the early or middle stage once the reaction is influenced with oxygen in the air, provision of an oxygen-preventing layer on the surface of the layer formed by the photosensitive composition is further required. Therefore, the dye-containing layer preferably further has an oxygen-preventing property. One of means for this end includes a method for incorporating a water-soluble or alkali-soluble resin (A) to the layer.

Near-Infrared-Absorbing Dye

Near-infrared-absorbing dyes which may be employed in the composition for the dye-containing layer have absorption wavelength within a range of 600 to 1100 nm. The near-infrared-absorbing dyes include, for example, but are not particularly limited to sensitizing dyes known to those skilled in the art, such as naphthoquinone dyes, anthraquinone dyes, phthalocyanine dyes, cyanine dyes and polymethine dyes. Among others, cyanine dyes and polymethine dyes are preferable. Particularly preferable dyes are those having maximum absorption wavelength of 800 to 860 nm. Single near-infrared-absorbing dye may be used solely or plural near-infrared-absorbing dyes may be used.

The most preferable embodiments of the near-infrared-absorbing dyes are listed below in way of exemplification, but not limitation.

Cyanine dyes having quinoline structure, such as 1-ethyl-4-[5-(1-ethyl-4(1H)-quinolinylidene)-1,3-pentadienyl]quinolinium iodide (maximum absorption wavelength: 814 nm; MeOH): 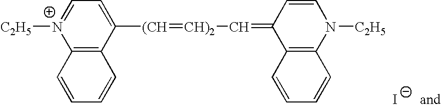
1-ethyl-2-[7-(1-ethyl-2(1H)-quinolinylidene)-1,3,5-heptatrienyl]quinolinium iodide (maximum absorption wavelength: 817 nm; MeOH):

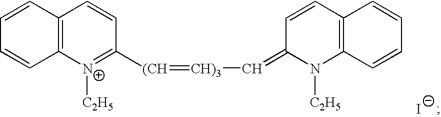

Cyanine dyes having benzopyrylium structure, such as 8-[(6,7-dihydro-2,4-diphenyl-5H-1-benzopyran-8-yl)methylene]5,6,7,8-tetrahydro-2,4-diphenyl-1-benzopyrylium perchlorate (maximum absorption wavelength: 840 nm; dichloroethane):

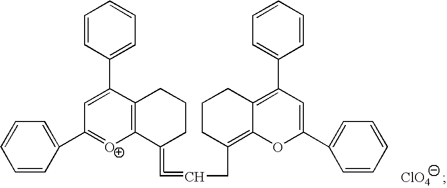

Cyanine dyes having benzothiazole structure, such as 5-chloro-2-[2-[3-[2-(5-chloro-3-ethyl-2(3H)-benzothiazolylidene)ethylidene]-2-diphenylamino-1-cyclopenten-1-yl]ethenyl]-3-ethylbenzothiazolium perchlorate (maximum absorption wavelength: 825 nm; DMSO): 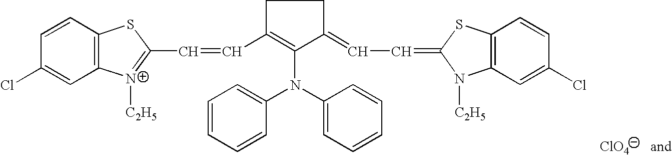
3-ethyl-2-[2-[3-[2-(3-ethyl-2(3H) -benzothiazolylidene)ethylidene]-2-diphenylamino-1-cyclopenten-1-yl]ethenyl]benzothiazolium perchlorate (maximum absorption wavelength: 831 nm; DMSO):

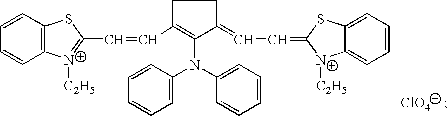

Cyanine dyes having indole structure, such as 2-[2-[2-chloro-3-[(3-ethyl-1,3-dihydro-1,1-dimethyl-2H-benz[e]indol-2-ylidene)ethylidene]-1-cyclohexen-1-yl]ethenyl]-1,1-dimethyl-3-ethyl-1H-benz[e]indolium tetrafluoroborate (maximum absorption wavelength: 816 nm; MeOH): 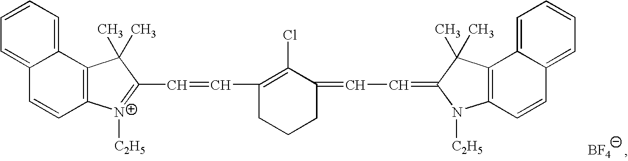
3-butyl-1,1-dimethyl-2-[2[2-diphenylamino-3-[(3-butyl-1,3-dihydro-1,1-dimethyl-2H-benz[e]indol-2-ylidene)ethylidene]-1-cyclopenten-1-yl]ethenyl]-1H-benz[e]indolium perchlorate (maximum absorption wavelength: 830 nm; MeOH): 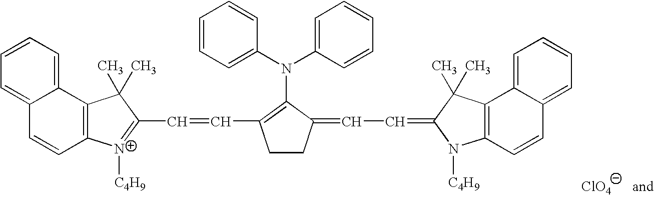
2-[2-[2-chloro-3-[(3-ethyl-1,3-dihydro-1,1-dimethyl-2H-benz[e]indol-2-ylidene)ethylidene]-1-cyclopentene-1-yl]ethenyl]-1,1-dimethyl-3-ethyl-1H-benz[e]indolium iodide (maximum absorption wavelength: 841 nm; MeOH):

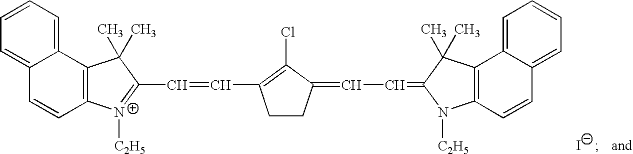

Polymethine dyes such as 1,1,5,5-tetrakis[4-(diethylamino)phenyl]-1,4-pentadien-3-ylium p-toluenesulfonate (maximum absorption wavelength: 817 nm; AcCN (acetonitrile)): 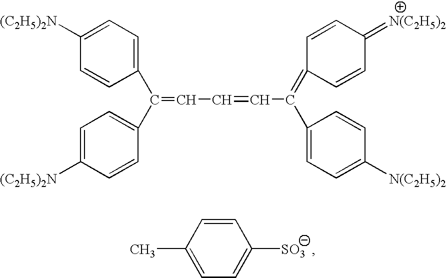
1,5-bis[4-(diethylamino)phenyl]-1,5-bis(4-methoxyphenyl)-1,4-pentadien-3-ylium trifluoromethanesulfonate (maximum absorption wavelength: 819 nm; AcCN): 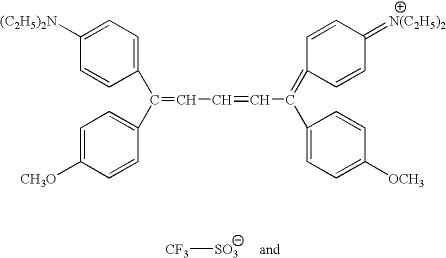
1,1,5,5-tetrakis[4-(diethylamino)phenyl]-1,4-pentadien-3-ylium butyl(triphenyl)borate (maximum absorption wavelength: 820 nm; AcCN):

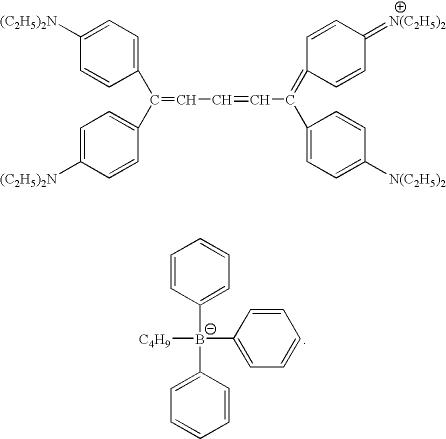

Water-Soluble or Alkali-Soluble Resin (A)

Examples of the water-soluble or alkali-soluble resin (A), which can be employed in the dye-containing layer comprised in the present invention, include, but are not limited to, (i) polyvinyl alcohols such as partially saponified polyvinyl acetates (saponification degree: 70 to 99 mol %), maleic modified and partially saponified polyvinyl acetates, itaconic modified and partially saponified polyvinyl acetates, ethylenically modified and partially saponified polyvinyl acetates, a known water-soluble resin such as “EXCEVAL (product name)” produced by KURARAY CO., LTD. (e.g., RS polymers such as RS-4103, RS-4104, RS-4105, RS-3110, RS-2113, RS-2117, RS-1117, RS-2817, RS-2617, RS-1717, RS-1113, RS-2713, RS-1713), and a known water-soluble resin such as “GOHSEFIMER (product name)” produced by Nippon Synthetic Chemical Industry Co., Ltd. (e.g., GOHSEFIMER Z series such as Z-200, Z-200H, Z-100, Z-210, Z-320); (ii) gelatins; (iii) gum arabic; (iv) polyethyleneoxides; (v) polypropyleneoxides; (vi) polyvinylpyrrolidones such as polyvinylpyrrolidone, a copolymer of a vinylpyrrolidone with vinyl acetate, and alkylated polyvinylpyrrolidones; (vii) a copolymer of methylvinyl ether with maleic anhydride; (viii) celluloses such as hydroxyethyl cellulose, hydroxypropyl cellulose, hydroxypropylmethyl cellulose and carboxymethyl cellulose; (ix) a copolymer of an unsaturated carboxylic acid (e.g. acrylic acid, methacrylic acid, itaconic acid and the like) with an ethylenically unsaturated compound (e.g. styrene, α-methylstyrene, acrylonitrile, acryl esters and the like), such as a copolymer of styrene and α-methylstyrene with acrylic acid; and mixture thereof. Polyvinyl alcohols, polyvinylpyrrolidones, a copolymer of methylvinyl ether with maleic anhydride, and a copolymer of an unsaturated carboxylic acid with an ethylenically unsaturated compound are preferable. The water-soluble or alkali-soluble resin (A) may be used alone to prepare a dye-containing layer solution, each resins (i) to (viii), in a form of aqueous solution, may be used to prepare a dye-containing layer solution, and the resin (ix), in a form of an aqueous ammonium solution, may be used to prepare a dye-containing layer solution. The resulting dye-containing layer solution can be applied, and then dried on the photosensitive layer to form a dye-containing layer.

Content of the near-infrared-absorbing dye in the composition for the dye-containing layer which is employed in the present invention is 0.1 to 30 parts by weight, preferably 0.2 to 30 parts by weight relative to 100 parts by weight of solid content of the dye-containing layer. When the content of the near-infrared-absorbing dye is less than 0.1 part by weight, insufficient absorption of the light provides insufficient cure of the photosensitive layer. When the content is more than 30 parts by weight, absorbed light failed to reach the boundary between the photosensitive layer and the dye-containing layer, and therefore, it is difficult to cure the photosensitive layer.

According to the present invention, it is desirable that the dye-containing layer is applied in an amount of 0.5 to 2.5 g/m², preferably 0.5 to 2.0 g/m², more preferably 0.5 to 1.5 g/m² as a basis of the solid content. When the applied amount is less than 0.5 g/m², it is difficult to adequately prevent oxygen. When the applied amount is more than 2.5 g/m², it is difficult to dry the layer.

Preparation Procedure for Dye-Containing Layer Solution

Solvent-Soluble Type Dye-Containing Layer Solution

In the present invention, preparation procedure for a dye-containing layer solution comprises
(i) dissolving a composition for dye-containing layer into a solvent.

The solvent which can be employed in the above step (i) includes, but is not particularly limited to, a solvent which can dissolve the near-infrared-absorbing dye, such as methyl ethyl ketone, cyclohexanone and N-methylpyrrolidone, dimethylformamide. Methyl ethyl ketone and dimethylformamide are preferable.

Water-Soluble Type Dye-Containing Layer Solution

In the present invention, preparation procedure for a dye-containing layer solution comprises
(i) dissolving a composition for dye-containing layer free of a water-soluble or alkali-soluble resin (A) into a solvent,
(ii) adding a water-soluble solvent thereto, and
(iii) adding a water-soluble or alkali-soluble resin (A) thereto.

The solvent which can be employed in the above step (i) includes, but is not particularly limited to, a solvent which can dissolve the near-infrared-absorbing dye, such as methyl ethyl ketone, cyclohexanone and N-methylpyrrolidone, dimethylformamide. Methyl ethyl ketone and dimethylformamide are preferable.

The water-soluble solvent which can be employed in the above step (ii) includes methanol, isopropyl alcohol, methoxypropanol, propyleneglycol and ethyleneglycol. Methoxypropanol and methanol are preferable.

As described above, when the dye-containing layer contains the water-soluble or alkali-soluble resin (A), the water-soluble or alkali-soluble resin (A) may be added as an aqueous solution or an aqueous ammonium solution in the above step (iii). Alternatively, a method which comprises dispersing a near-infrared-absorbing dye with an emulsifier and without any solvent may be employed.

Third Layer

The third layer may be applied on the dye-containing layer comprising the near-infrared-absorbing dye of the present lithographic printing plate material for CTP as described above. The provision of the third layer has advantages in complement and improvement of oxygen-preventing ability of the dye-containing layer, stability in a bright room, and the like, when these properties have been insufficient.

Water-Soluble or Alkali-Soluble Resin

According to the present invention, the water-soluble or alkali-soluble resin which can be used in the third layer include, for example, water-soluble or alkali-soluble resins similar to those used in the dye-containing layer containing near-infrared-absorbing dye as described above. The third layer can be formed on the dye-containing layer according to the similar procedures as described above.

Method for improving stability in a bright room of the photosensitive composition includes use of a nitroxyl compound, use of an organic pigment and the like, and combination thereof. The nitroxyl compound is described hereinafter.

Nitroxyl Compound

The lithographic printing plate material of the present invention may further include a nitroxyl compound as an additional component. The nitroxyl compound may be contained in the photosensitive composition to be formed to the photosensitive layer, the composition for the dye-containing layer or both of the photosensitive composition and the composition for the dye-containing layer. Alternatively, the nitroxyl compound may be contained in the third layer. The nitroxyl compound can significantly improve storage stability and stability in a bright room of the photosensitive composition according to the present invention, especially the lithographic printing plate material for CTP (Computer-to-Plate), which has photosensitivity to the light having wavelength of 830 nm.

The nitroxyl compounds include nitroxyl compounds which have been conventionally used in the art, for example, such that specifically described in JP-A-10-97059 corresponding to EP0828195, but are not limited to di-tert-butylnitroxyl, 1-oxyl-2,2,6,6-tetramethylpiperidine, 1-oxyl-2,2,6,6-tetramethylpiperidin-4-ol, 1-oxyl-2,2,6,6-tetramethylpiperidin-4-one, 1-oxyl-2,2,6,6-tetramethylpiperidin-4-ylacetate, 1-oxyl-2,2,6,6-tetramethylpiperidin-4-yl-2-ethylhexanoate, 1-oxyl-2,2,6,6-tetramethylpiperidin-4-ylstearate, 1-oxyl-2,2,6,6-tetramethylpiperidin-4-ylbenzoate, 1-oxyl-2,2,6,6-tetramethylpiperidin-4-yl 4-tert-butylbenzoate, bis(1-oxyl-2,2,6,6-tetramethylpiperidin-4-yl)succinate, bis(1-oxyl-2,2,6,6-tetramethylpiperidin-4-yl)adipate, bis(1-oxyl-2,2,6,6-tetramethylpiperidin-4-yl)sebacate, bis(1-oxyl-2,2,6,6-tetramethylpiperidin-4-yl)-n-butylmalonate, bis(1-oxyl-2,2,6,6-tetramethylpiperidin-4-ly)phthalate, bis(1-oxyl-2,2,6,6-tetramethylpiperidin-4-yl)isophthalate, bis(1-oxyl-2,2,6,6-tetramethylpiperidin-4-yl)terephthalate, bis(1-oxyl-2,2,6,6-tetramethylpiperidin-4-yl)hexahydroterephthalate, N,N′-bis(1-oxyl-2,2,6,6-tetramethylpiperidin-4-yl)adipamide, N-(1-oxyl-2,2,6,6-tetramethylpiperidin-4-yl)caprolactam, N-(1-oxyl-2,2,6,6-tetramethylpiperidin-4-yl)dodecylsuccinimide, 2,4,6-tris(1-oxyl-2,2,6,6-tetramethylpiperidin-4-yl)isocyanurate, 2,4,6-tris[N-butyl-N-(1-oxyl-2,2,6,6-tetramethylpiperidin-4-yl)]-S-triazine and 4,4′-ethylenebis(1-oxyl-2,2,6,6-tetramethylpiperadin-3-one). The most preferable is bis(1-oxyl-2,2,6,6-tetramethylpiperidin-4-yl)sebacate.

When the nitroxyl compound is contained in the photosensitive composition, content of the nitroxyl compound in the composition is 0.001 to 1 part by weight, preferably 0.001 to 0.5 part by weight, more preferably 0.001 to 0.3 part by weight relative to 100 parts by weight of the total amount of the ethylenically unsaturated compound and the alkali-soluble resin (B). When the content of the nitroxyl compound is less than 0.001 part by weight, effects such as storage stability and stability in a bright room can not be obtained. When the content is more than 1 part by weight, it is difficult to cure the photosensitive layer.

When the nitroxyl compound is contained in the composition for the dye-containing layer, content of the nitroxyl compound in the composition is 0.001 to 1 part by weight, preferably 0.002 to 0.5 part by weight, more preferably 0.002 to 0.3 part by weight relative to 100 parts by weight of solid content of the composition. When the content of the nitroxyl compound is less than 0.001 part by weight, effects such as stability in a bright room can not be obtained. When the content is more than 1 part by weight, it is difficult to cure the photosensitive layer.

Alternatively, when the nitroxyl compound is contained in both of the photosensitive composition and the composition for the dye-containing layer, the content of the nitroxyl compound is the same that described above in each case.

Organic Pigment and/or Water-Soluble Dye

Another embodiment of the present invention providing improved stability in a bright room includes a method comprising incorporating an organic pigment and/or a water-soluble dye into the dye-containing layer or the third layer. Concretely, absorbing wavelength and absorbance of the dye-containing layer or the third layer can be adjusted to prevent light of ultraviolet screened white fluorescent lamp (having emitting wavelength: 400 to 700 nm) or yellow lamp (having emitting wavelength: 500 to 700 nm) adequately. Preferable absorbance is no less than 2.0 (i.e. prevention rate=99% and more).

The organic pigment may include conventionally known any insoluble organic pigment absorbing light at 400 to 800 nm, especially, which is selected from organic pigments such as insoluble azo pigments such as monoazo pigments, disazo pigments, metal complexes; azolake pigments; phthalocyanine pigments; anthraquinone pigments; thioindigo pigments; perylene pigments; perynone pigments; quinacridone pigments; isoindolinone pigments; dioxazine pigments; quinophthalone pigments; and diketopyrrolopyrrole pigments. The water-soluble dye desirably includes anion dyes having sulfonate structure. Two or more of these may be combined and used to accomplish the desired light absorption.

Examples of the organic pigment which can be employed in the dye-containing layer include C. I. Pigment Yellow 1, C. I. Pigment Yellow 12, C. I. Pigment Red 22, C. I. Pigment Red 254, C. I. Pigment Violet 1, C. I. Pigment Violet 23, C. I. Pigment Blue 1, C. I. Pigment Blue 15, C. I. Pigment Blue 15:4, etc. Azo dyes and phthalocyanine dyes are particularly preferable.

Content of the organic pigment and/or the water-soluble dye is 25 to 50 parts by weight, preferably 30 to 45 parts by weight, more preferably 30 to 35 parts by weight relative to 100 parts by weight of the water-soluble or alkali-soluble resin for the dye-containing layer or the third layer. When the content is less than 25 parts by weight, prevention from bright safe light such as ultraviolet screened all-round light and yellow light is insufficient, which results in cure of the photosensitive layer under long term exposure of the safe light. When the content is more than 50 parts by weight, it adversely influences on the oxygen preventability, which results in no image formation.

Matting Agent

In an apparatus automatically feeding printing plate materials, when one single printing plate material is separately conveyed with a suction cup from a pile of plural (generally, about 500 sheets of) the plate materials without insertion of a slip sheet between the plate materials, there are problems such as suction up of some plate materials at the time due to the even contact between the plate materials. To solve such problems, the followings are considered: incorporation of resin particles into a layer such as the photosensitive layer and the covering layer formed thereon, and use of a gravure roll or the like to form surface roughness on the photosensitive layer, the covering layer formed thereon, or the like (see JP-A-2000-235255, JP-A-51-96604, JP-A-55-12974 corresponding to U.S. Pat. No. 5,028,512, JP-A-58-182636 corresponding to U.S. Pat. No. 4,557,994 and the like). The matting agent may be preferably incorporated into any one of the photosensitive layer, the dye-containing layer and the third layer, more preferably the most upper layer.

In the present invention, it is preferable to incorporate a matting agent in order to solve the above problem of suction up of the plural plate materials at once. It is desirable that the matting agent which may be employed in the present lithographic printing plate material has average particle size of 3 to 20 μm, preferably 5 to 15 μm, more preferably 6 to 12 μm. When the average particle size of the matting agent is less than 3 μm, the suction up of the plural plate materials frequently occurs. When the average particle size of the matting agent is more than 12 μm, the plate materials slide on the pile, and therefore well piled materials can not be maintained, as well as, laser light is diffused on the printing plate material, and therefore the sharp image can not be obtained. It is also desirable that the matting agent has particle size distribution of 1 to 30 μm, preferably 1 to 25 μm, more preferably 1 to 20 μm.

The matting agent which can be used in the present lithographic printing plate material includes, but is not limited to, inorganic materials such as silica particles, organic materials such as crosslinked resin particles such as crosslinked poly(methyl methacrylate), crosslinked polystyrene, etc. The crosslinked resin particles are preferable, since particles are deformed upon piling the plate materials provided that these particles are corresponds to the organic material and these have not crosslinked.

It is desirable that content of the matting agent is 0.05 to 0.5% by weight, preferably 0.1 to 0.45% by weight, more preferably 0.15 to 0.4% by weight relative to solid content of the composition for the photosensitive layer, the dye-containing layer or the third layer. When the content of the matting agent is less than 0.05% by weight, the suction up of the plural plate materials at once frequently occurs as described above. When the content of the matting agent is more than 0.5% by weight, the printing plate materials slide thereon upon piling these plate materials, and therefore well piled materials can not be maintained, as well as, laser light is diffused on the printing plate material, and therefore the sharp image can not be formed.

According to the present invention, the dye-containing layer or the third layer may contain further additives such as fine particle filler such as colloidal silica, surfactant to improve coating applicability, and antifoaming agent.

The method for producing the present lithographic printing plate material for CTP comprises
(a) forming a photosensitive layer on a substrate, and
(b) forming a dye-containing layer on the photosensitive layer.

Another embodiment of the method for producing the present lithographic printing plate material for CTP comprises
(a) forming a photosensitive layer on a substrate,
(b) forming a dye-containing layer on the photosensitive layer, and
(c) forming the third layer on the dye-containing layer.

The above-described matting agent may be contained in the photosensitive layer, the dye-containing layer and/or the third layer. The former producing method may further comprise a step (b′) forming a layer comprising a matting agent on the dye-containing layer, after the step (b), to incorporate the matting agent into the present lithographic printing plate material for CTP. The latter producing method may further comprise a step (c′) forming a layer comprising a matting agent on the third layer, after the step (c), to incorporate the matting agent into the present lithographic printing plate material for CTP. In these step (b′) and (c′), the method for forming a layer comprising a matting agent includes, but is not particularly limited to, a method comprising spraying an appropriate binder resin and a matting agent with an organic solvent, and then drying to form a layer, etc. As described above, in the apparatus automatically feeding printing plate materials, when one single printing plate material is separately conveyed with a suction cup from a pile of the plural plate materials without insertion of a slip sheet between the plate materials, there are problems such as suction up of some plate materials at the time due to the even contact between the plate materials. To solve these problems more effectively, it is preferable that the matting agent is contained in the dye-containing layer without disadvantages such as increased steps.

In the step (a) described above, the method for applying the photosensitive layer on the substrate includes, but is not particularly limited to, for example, methods comprising application with a natural coater, a reverse coater, a gravure coater, a curtain coater, air spraying, airless spraying, a bar coater, a knife coater, a spin coater or the like, and then, for example, drying at 40 to 150° C. for 0.1 to 10 minutes. It is preferable that the applied amount after drying is approximately 0.5 to 2.0 g/m².

In the step (b) described above, the method for applying the dye-containing layer on the photosensitive layer includes, but is not particularly limited to, similar application methods to those in the step (a), for example, methods comprising application with a natural coater, a reverse coater, a gravure coater, a curtain coater, air spraying, airless spraying, a bar coater, a knife coater, a spin coater or the like, and then, for example, drying at 40 to 150° C. for 0.1 to 10 minutes.

The method for applying the dye-containing layer or the third layer on the dye-containing layer includes, but is not particularly limited to, for example, methods comprising application with a natural coater, a reverse coater, a gravure coater, a curtain coater, air spraying, airless spraying, a bar coater, a knife coater, a spin coater or the like, and then, for example, drying at 40 to 150° C. for 0.1 to 10 minutes. It is preferable that the applied amount after drying is approximately 1.0 to 2.5 g/m².

The present method for producing a lithographic printing plate for CTP comprises, on the lithographic printing plate material for CTP as described above,
(i) exposing and drawing with a semiconductor laser having wavelength of 830 nm as a light source,
(ii) optionally rinsing the dye-containing layer with water,
(iii) developing the photosensitive layer and the dye-containing layer with an alkaline-aqueous developer,
(iv) treating with a desensitizing agent, and
(v) optionally heating.

As described above, the composition for dye-containing layer which can be employed in the present invention can comprise the water-soluble or alkali-soluble resin, and therefore, the composition can be subjected to development with an alkaline-aqueous developer. Accordingly, the above-described step (ii) is spontaneous. Additionally, in the case that the shortened plate producing time is required or the like, such step may be added.

The desensitizing agent used in the above step (iv) includes, but is not particularly limited to, the conventional desensitizing agents in such purpose. Generally, the desensitizing agents are commercially available which are referred to as “finishing gum” or “plate surface protect agent”. Plate surface can be treated by a method comprising diluting such desensitizing agents with water, rubbing the plate surface with a sponge containing the aqueous solution to apply the agent, and drying, or by a method comprising applying and drying the agent in an automatically applying apparatus, etc.

Followed by the desensitizing treatment, in the above step (v), heat treatment (i.e. heating) may be conducted, if necessary. Preferable heating conditions are as follows: temperature at 80 to 150° C. for 0.1 to 5 minutes.

The lithographic printing plate for CTP obtainable by the above-described producing method also falls within the scope of the present invention.

Although only some exemplary embodiments of the present invention have been described in detail above, those skilled in the art will readily appreciated that many modifications are possible in the exemplary embodiments without materially departing from the novel teachings and advantages of this invention. Accordingly, all such modifications are intended to be included within the scope of this invention.

### EXAMPLES

The present invention is further described below according to the following Examples in only way of exemplification, but the present invention is not limited to these Examples.

Photosensitive Layer

Components in the following Table 1 were combined and formulated with stirring to prepare a sensitizing solution of photosensitive composition in an organic solvent (organic solvent: methoxypropanol, solid content=8%). The sensitizing solution was applied on an aluminum substrate, which had been subjected to hydrophilization, with a bar coater, and then dried at 80° C. for 5 minutes to form a photosensitive layer. The applied amount after drying was about 1 g/m². Coating conditions of the photosensitive layer after 1 hour or 24 hours of time between the preparation of the sensitizing solution and the application-dying of the sensitizing solution were evaluated. The results are shown in the following Tables 4 and 5.

Dye-Containing Layer

The components in Table 2 or 3 were combined and formulated with stirring to prepare an aqueous solution of the composition for dye-containing layer (solid content=4%) and a solution for a dye-containing layer in a solvent (solid content=4%). However, the dye-containing layer solution II was prepared by dissolving a near-infrared-absorbing dye in methyl ethyl ketone (MEK), adding thereto a water-soluble solvent methoxypropanol (PM), and combining with a solution of POVAL 205 dissolved in deionized water (DIW) with stirring. The dye-containing layer solution III was prepared by dissolving a near-infrared-absorbing dye and a nitroxyl compound in methyl ethyl ketone (MEK), adding thereto a water-soluble solvent methoxypropanol (PM), and combining with a solution of POVAL 205 dissolved in deionized water (DIW) with stirring. The dye-containing layer solution IV was prepared by dissolving an organoborate in methyl ethyl ketone (MEK), adding thereto a water-soluble solvent methoxypropanol (PM), and combining with a solution of POVAL 205 dissolved in deionized water (DIW) with stirring.

Each of the dye-containing layer solutions was applied on the aluminum substrate, on which the sensitizing solution had been applied, with a bar coater, and then dried at 80° C. for 5 minutes to form a dye-containing layer. The applied amount after drying was about 1.5 g/m².

TABLE 1

| | Formulation of photosensitive | | |
|---|---|---|---|
| | composition | | |
| | A | B | C |
| Alkali-soluble resin (*1) | 60 | 60 | 60 |
| DPHA (*2) | 140 | 140 | 140 |
| Near-infrared-absorbing dye (*3) | — | 5 | 5 |
| Organoborate (*4) | 5 | 5 | — |
| Triazine (*5) | 5 | 5 | 5 |
| Nitroxyl compound (*6) | — | 0.5 | — |
| Pigment (*7) | 10 | 10 | 10 |
| Solvent (PM/MEK) | 2736 | 2593 | 2593 |

TABLE 2

| | Formulation of dye-containing | | |
|---|---|---|---|
| | layer solution | | |
| | I | II | III |
| POVAL 205 (*8) | 100 | 100 | 100 |
| Near-infrared-absorbing dye (*3) | — | 4 | — |
| Nitroxyl compound (*6) | — | 0.1 | 0.1 |
| Organoborate (*4) | — | — | 4 |
| MEK | — | 550 | 550 |
| PM | — | 420 | 420 |
| DIW | 2440 | 1530 | 1530 |

TABLE 3

Formulation of dye-containing
layer solution

| | IV | V |
|---|---|---|
| POVAL 205 (*8) | 100 | 100 |
| Near-infrared-absorbing dye (*3) | 2 | 7 |
| MEK | 500 | 800 |
| PM | 400 | 420 |
| DIW | 1550 | 1350 |

(*1) acrylic copolymer resin having acrylic groups and carboxyl groups as side chain, wherein these acryl groups have been introduced by reaction with an alicyclic epoxy group-containing ethylenically unsaturated compound (i.e., 3,4-epoxycyclohexylmethyl acrylate), which is produced and available from DAICEL CHEMICAL INDUSTRIES, LTD.
(*2) dipentaerythritol hexaacrylate
(*3) 2-[2-[2-chloro-3-[(3-ethyl-1,3-dihydro-1,1-dimethyl-2H-benz[e]indol-2-ylidene)ethylidene]-1-cyclohexen-1-yl]ethenyl]-1,1-dimethyl-3-ethyl-1H-benz[e]indolium tetrafluoroborate (maximum absorption wavelength: 816 nm)
(*4) tetra-n-butyl ammonium triphenyl-n-butylborate
(*5) 2,4,6-tris(trichloromethyl)-S-triazine
(*6) IRGASTAB UV10: bis(1-oxyl-2,2,6,6-tetramethylpiperidin-4-yl)cebacate (produced by Ciba)
(*7) phthalocyanine blue (FASTOGEN Blue NK manufactured by DAINIPPON INK AND CHEMICALS INCORPORATED)
(*8) polyvinyl alcohol produced by KURARAY CO., LTD. (partially saponified polyvinyl acetate)

### Examples 1 to 3 and Comparative Examples 1 and 2

The prepared lithographic printing plate material was evaluated on image remaining property, stability in a bright room, rubbing resistance as an alternative of printing durability, and ink scumming. Results are shown in the following Tables 4 and 5. According to the following evaluation procedures, these properties were evaluated on both of the printing plate material 1 day after the preparation and the printing plate material after 7 days storage, under conditions at 45° C. and 75% relative humidity, after its preparation. The testing procedures are as follows.

Testing Procedures

(1) Coating Conditions of Photosensitive Layer

Conditions of the coating of the resulted photosensitive layer were visually observed and evaluated according to the following valuation basis.

Valuation Basis

◯: Smooth surface

×: Scratches due to blobbing (insoluble ingredients) was observed. However, application of filtrate of the sensitizing solution provided smooth surface.

(2) Image Remaining Property

The prepared printing plate material was exposed and drawn (at 6W) with Creo Trendsetter NEWS by using 50% screening pattern. A developer (DH-N) (produced by Fuji Photo Film Co., Ltd.) which had been diluted with water (x4) was poured into a brush type automatic processing machine. Development proceeded at 30° C. After development, the printing plate material was rinsed with water and dried in air to form an image. The resulted image was visually evaluated and image remaining property was determined in accordance with the following valuation basis.

Valuation Basis

◯: formation of sharp image

Δ: formation of image accompanied with insufficient profiled film remaining property

×: no image remaining

(3) Stability in Bright Room

The prepared lithographic printing plate material was exposed under a yellow lamp for 5 hours.

The material was exposed and drawn (at 6W) with Creo Trendsetter NEWS by using 50% screening pattern. A developer (DH-N) (produced by Fuji Photo Film Co., Ltd.) which had been diluted with water (x4) was poured into a brush type automatic processing machine. Development proceeded at 30° C. After development, the printing plate material was rinsed with water and dried in air to form an image. The resulted image was visually evaluated and stability in a bright room was evaluated in accordance with the following valuation basis.

Valuation Basis

◯: formation of sharp image

Δ: formation of image accompanied with unnecessary film residue

×: insufficient development all over the material

(4) Rubbing Resistance

Thus formed imaged area was evaluated by using a rubbing tester (RUBBING TESTER manufactured by TAIHEIRIKA). After felt parts for the rubbing tester (produced by TAIHEIRIKA) was set on the rubbing tester and sufficiently wetted with an etching solution (DON-H NS-7 produced by NISSIN Corporation) to contact with the imaged area, the printing plate was rubbed with 2 kg of load at 500 times. Adhesion of the imaged area onto the substrate as well as abrasiveness of the imaged area were visually evaluated. Rubbing resistance was determined in accordance with the following valuation basis.

Valuation Basis

⊚: sharp image remaining with no abrasion

◯: sharp image remaining with slight abrasion

Δ: image remaining with little abrasion

×: image remaining with much abrasion

(5) Ink Scumming

A developer (DH-N) (produced by Fuji Photo Film Co., Ltd.) which had been diluted with water (x4) was poured into a brush type automatic processing machine. Printing plate material without laser exposing and drawing was developed at 30° C. After, development, the printing plate material was rinsed with water, subjected to squeezing and gumming and dried at 70° C. for 1 minute. Residual gum was removed with running water for 30 seconds, and then the printing plate material was dried at 70° C. for 2 minutes. Newspaper ink was applied thereon by a roller and it was left for 30 minutes at room temperature. The applied ink was swelled with running water for 20 seconds, and then wiped off with cotton waste (cotton cloth) while water was running. After air drying, ink scumming was visually evaluated. Ink scumming was determined in accordance with the following valuation basis.

Valuation Basis

⊚: No scumming

◯: Remaining slight black stain

Δ: Remaining black stain

×: Blackened

Test Results

TABLE 4

| | Examples | | | | | |
|---|---|---|---|---|---|---|
| | 1 | | 2 | | 3 | |
| Formulation of photo- | A | | A | | A | |
| sensitive composition | | | | | | |
| Formulation of compo- | II | | IV | | V | |
| sition for dye- | | | | | | |
| containing layer | | | | | | |
| Time between preparation | 1 | 24 | 1 | 24 | 1 | 24 |
| of photosensitive compo- | | | | | | |
| sition and application- | | | | | | |
| drying (h) | | | | | | |
| Coating conditions | ◯ | ◯ | ◯ | ◯ | ◯ | ◯ |

Image remaining property

| | | | | | | |
|---|---|---|---|---|---|---|
| 1 day after preparation | ◯ | ◯ | ◯ | ◯ | ◯ | ◯ |
| After storage | ◯ | ◯ | ◯ | ◯ | ◯ | ◯ |

Stability in bright room

| | | | | | | |
|---|---|---|---|---|---|---|
| 1 day after preparation | ◯ | ◯ | ◯ | ◯ | ◯ | ◯ |
| After storage | ◯ | ◯ | ◯ | ◯ | ◯ | ◯ |

Rubbing resistance

| | | | | | | |
|---|---|---|---|---|---|---|
| 1 day after preparation | ◯ | ◯ | ◯ | ◯ | ◯ | ◯ |
| After storage | ◯ | ◯ | ◯ | ◯ | ◯ | ◯ |

Ink scumming

| | | | | | | |
|---|---|---|---|---|---|---|
| 1 day after preparation | ⊚ | ⊚ | ⊚ | ⊚ | ⊚ | ⊚ |
| After storage | ⊚ | ⊚ | ⊚ | ⊚ | ⊚ | ⊚ |

TABLE 5

| Comparative Examples | |
|---|---|
| 1 | 2 |

| Formulation of photosensitive | B | | C | |
|---|---|---|---|---|
| composition | | | | |
| Formulation of composition | I | | III | |
| for dye-containing layer | | | | |
| Time between preparation of | 1 | 24 | 1 | 24 |
| photosensitive composition | | | | |
| and application-drying (h) | | | | |
| Coating conditions | ◯ | X | ◯ | ◯ |

Image remaining property

| | | | | |
|---|---|---|---|---|
| 1 day after preparation | ◯ | ◯ | Δ | Δ |
| After storage | ◯ | Δ | Δ | Δ |

Stability in bright room

| | | | | |
|---|---|---|---|---|
| 1 day after preparation | ◯ | ◯ | Δ | Δ |
| After storage | ◯ | ◯ | Δ | Δ |

Rubbing resistance

| | | | | |
|---|---|---|---|---|
| 1 day after preparation | ◯ | ◯ | X | X |
| After storage | ◯ | X | X | X |

Ink scumming

| | | | | |
|---|---|---|---|---|
| 1 day after preparation | ⊚ | ⊚ | ⊚ | ⊚ |
| After storage | ⊚ | ⊚ | ⊚ | ⊚ |

According to the present invention, each of the lithographic printing plate materials for CTP of Examples 1 to 3 was prepared by using sensitizing solution free of near-infrared-absorbing dye and dye-containing layer solution containing near-infrared-absorbing dye. Even if the prepared sensitizing solution was allowed to be left for 24 hours, blobbing, i.e. insoluble materials could not be produced, and the resulted coating was flat and had excellent appearance. It was also found that the resulted lithographic printing plate material had good image remaining property, stability in a bright room, rubbing resistance as an alternative of printing durability, and ink scumming, even if it was after 7 days storage under such accelerating conditions.

Whereas, according to the lithographic printing plate material of Comparative Example 1, wherein sensitizing solution contains near-infrared-absorbing dye, the sensitizing solution was left for 24 hours, which raised blobbing (insoluble materials) and gave significantly deteriorated coating. However, removal of blobbing, i.e. filtration off of the insoluble materials gave a smooth coating. A dye-containing layer was formed thereon to give a lithographic printing plate material, which had good image remaining property, stability in a bright room, rubbing resistance as an alternative of printing durability, and ink scumming after 1 day, and deteriorated image remaining property and rubbing resistance after 7 days storage.

The lithographic printing plate material of Comparative Example 2, which comprises photosensitive layer containing near-infrared-absorbing dye and dye-containing layer (i.e. overcoat layer) containing organoboron anion-containing compound, was left for 24 hours, could not result in blobbing and gave a good smooth coating. However, image remaining property, stability in a bright room and rubbing resistance were deteriorated.

The photosensitive composition which can be employed in the present invention is useful for a printing plate material in a method referred to as Computer-to-Plate (CTP) method. The composition can also be applied to various resists such as a negative resist, which is exposed with a given light, wherein the exposed area is cured and unexposed area is to be subjected to alkaline development.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising”, “having”, “including”, and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventor for carrying out the invention. Variations of those preferred embodiments may become apparent to those skilled in the art upon reading the foregoing description. The inventor expects skilled artisans to employ such variations as appropriate, and the inventor intends for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

The disclosure of Japanese Patent Application No. 2006-4776 filed on Jan. 12, 2006 including specification and claims is incorporated herein by reference in its entirety.

1. A lithographic printing plate material for CTP, which comprises
a substrate,
a photosensitive layer formed on the substrate, and
a dye-containing layer formed on the photosensitive layer, wherein the photosensitive layer is formed by a photosensitive composition comprising a halomethyl group-containing compound and an organoboron anion-containing compound, and wherein the dye-containing layer is formed by a composition for dye-containing layer, which comprises a near-infrared-absorbing dye.

2. The lithographic printing plate material for CTP according to claim 1, wherein the photosensitive composition is free of a near-infrared-absorbing dye.

3. The lithographic printing plate material for CTP according to claim 1, wherein the substrate is an aluminum substrate, and the composition for dye-containing layer further comprises a water-soluble or alkali-soluble resin (A).

4. The lithographic printing plate material for CTP according to claim 3, wherein the photosensitive composition further comprises an ethylenically unsaturated compound and an alkali-soluble resin (B).

5. The lithographic printing plate material for CTP according to claim 4, wherein the photosensitive composition comprises 0.1 to 20 parts by weight of the halomethyl group-containing compound and 0.1 to 20 parts by weight of the organoboron anion-containing compound, relative to 100 parts by weight of the ethylenically unsaturated compound and the alkali-soluble resin (B), and the weight ratio of the ethylenically unsaturated compound: the alkali-soluble resin (B) is 40:60 to 90:10.

6. The lithographic printing plate material for CTP according to claim 1, wherein content of the near-infrared-absorbing dye is 0.1 to 30 parts by weight relative to 100 parts by weight of solid content of the composition for dye-containing layer.

7. The lithographic printing plate material for CTP according to claim 4, wherein the photosensitive composition and/or the composition for dye-containing layer further comprise(s) a nitroxyl compound.

8. The lithographic printing plate material for CTP according to claim 7, wherein the photosensitive composition comprises 0.001 to 1 part by weight of the nitroxyl compound relative to 100 parts by weight of total amount of the ethylenically unsaturated compound and the alkali-soluble resin (B) with the proviso that the nitroxyl compound is comprised only in the photosensitive composition; the composition for dye-containing layer comprises 0.001 to 1 part by weight of the nitroxyl compound relative to 100 parts by weight of solid content of the composition for dye-containing layer with the proviso that the nitroxyl compound is comprised only in the composition for dye-containing layer; or
the photosensitive composition comprises 0.001 to 1 part by weight of the nitroxyl compound relative to 100 parts by weight of total amount of the ethylenically unsaturated compound and the alkali-soluble resin (B), and the composition for dye-containing layer comprises 0.001 to 1 part by weight of the nitroxyl compound relative to 100 parts by weight of solid content of the composition for dye-containing layer, with the proviso that the nitroxyl compound is comprised in both of the photosensitive composition and the composition for dye-containing layer.

9. The lithographic printing plate material for CTP according to claim 1, wherein the composition for dye-containing layer further comprises an organic pigment.

10. The lithographic printing plate material for CTP according to claim 1, wherein the photosensitive layer is applied in an amount of 0.5 to 2.0 g/m² (as a basis of the solid content) and the dye-containing layer is applied in an amount of 0.5 to 2.5 g/m² (as a basis of the solid content).

11. The lithographic printing plate material for CTP according to claim 1, wherein the photosensitive composition or the composition for dye-containing layer further comprises 0.05 to 0.5 part by weight of a matting agent relative to 100 parts by weight of solid content of the photosensitive composition or the composition for dye-containing layer.

12. The lithographic printing plate material for CTP according to claim 1, wherein the substrate is an aluminum substrate, and wherein the plate material further comprises the third layer on the dye-containing layer, which comprises a water-soluble or alkali-soluble resin (A).

13. A method for producing a lithographic printing plate material for CTP, which comprises
(a) forming a photosensitive layer on a substrate, and
(b) forming a dye-containing layer on the photosensitive layer, wherein a photosensitive composition comprising an ethylenically unsaturated compound, an alkali-soluble resin, a halomethyl group-containing compound and an organoboron anion-containing compound is applied and dried to form the photosensitive layer, and wherein a composition for dye-containing layer, which comprises a near-infrared-absorbing dye and a water-soluble or alkali-soluble resin, is applied and dried to form the dye-containing layer.

14. The method for producing a lithographic printing plate material for CTP according to claim 13, wherein the photosensitive layer and/or the dye-containing layer further comprises a nitroxyl compound.

15. A method for producing a lithographic printing plate for CTP, which comprises, on the lithographic printing plate material for CTP according to claim 1,
(i) exposing and drawing with a semiconductor laser having wavelength of 830 nm as a light source,
(ii) optionally rinsing the dye-containing layer with water to remove the layer,
(iii) developing the photosensitive layer, together with the dye-containing layer, with an alkaline-aqueous developer with the proviso that the dye-containing layer has not been rinsed with water not to remove the layer in the above step (ii),
(iv) treating with a desensitizing agent, and
(v) optionally heating.

16. A lithographic printing plate for CTP produced by the method according to claim 15.
